(19) United States
(12) Patent Application Publication
(10) Pub. No.: US 2010/0283124 A1
(43) Pub. Date: Nov. 11, 2010

(54) SEMICONDUCTOR DEVICE

(75) Inventors: Aya Ohmae, Tokyo (JP); Yuichi Mabuchi, Mito (JP); Atsushi Nakamura, Fuchu (JP)

Correspondence Address: MILES & STOCKBRIDGE PC, 1751 PINNACLE DRIVE, SUITE 500, MCLEAN, VA, 22102-3833, US

(73) Assignee: Renesas Electronics Corporation, Kawasaki-shi, Kanagawa (JP)

(21) Appl. No.: 12/747,923

(22) PCT Filed: Jan. 7, 2009
(86) PCT No.: PCT/JP2009/050047

§ 371 Date: Jul. 27, 2010

(30) Foreign Application Priority Data
Feb. 1, 2008 (JP) 2008-022750

(51) Int. Cl. H01L 27/06

(52) U.S. Cl. 257/532; 257/E27.011

(57) ABSTRACT

Provided is a semiconductor device in which impedances of power-supply wiring/GND wiring are matched with each other inside the semiconductor device to reduce a noise current without depending on a mounting layout of a circuit board. In a semiconductor device according to a typical embodiment of the present invention including: a package board; a semiconductor chip; a power-supply wiring; and a GND wiring, the semiconductor device includes a conductive plate, and further includes a first impedance adjusting element and a second impedance adjusting element. Parasitic capacitances of the power-supply wiring and the GND wiring are determined by the conductive plate, and the impedances of the power-supply wiring and the GND wiring are adjusted by the first impedance adjusting element and the second impedance adjusting element.

### TECHNICAL FIELD

The present invention relates to a technique capable of reducing noise current in a semiconductor device.

### BACKGROUND ART

In recent years, as an electronic control board on which an LSI (Large Scale Integrated Circuit) is mounted has been on increase, there has arisen a problem of EMI (Electro-Magnetic Interference) that harmonics of operation frequencies of the LSI becomes conduction or radiation noise to affect other devices.

As a main cause of the EMI generated by an electronic device and the like, high frequency current generated by a high-speed switching operation of an internal circuit such as the LSI can be cited. The high frequency current generated inside the LSI is propagated to a circuit board, and the radiation from the circuit board is caused. Further, the high frequency current is propagated to wirings and other boards through connectors connected to the circuit board, and the radiation may be caused. For this problem, a technique of preventing the propagation of the high frequency current from the LSI to the circuit board has been proposed.

For example, in Patent Document 1, a circuit board on which an LSI is mounted includes a first capacitor, a first-power supply wiring, a second power-supply wiring, and a second capacitor, all of which electrically connect power-supply terminals to via holes. A magnitude of a characteristic impedance of the power-supply wiring is set to be three or more times a magnitude of an impedance of the capacitor in a range of a predetermined frequency, and further, a length of the power-supply wiring is set to be equal to or larger than a value obtained by multiplying 20 mm with a wavelength shortening rate of the circuit board, and equal to or smaller than a value obtained by multiplying the wavelength shortening rate with a ¼ wavelength of an upper limit frequency of the predetermined frequency. With the configuration, an effect of a low frequency pass filter is increased.

Further, for example, Patent Document 2 discloses a configuration of a wiring board on which a predetermined wiring is arranged and an electromagnetic wave blocking film (metal foil) is arranged in a position adjacent to the wiring, and a configuration of a semiconductor device in which an insulating film is arranged on a surface where an integrated circuit of a semiconductor chip is formed, a lead is arranged on the electromagnetic wave blocking film through the insulating film, this lead and an external terminal of the semiconductor chip are electrically connected to each other, and the semiconductor device is sealed with a sealing material. With the configurations, an inductance of the wiring or a wiring formed of the lead inside the semiconductor package and inductive crosstalk can be reduced.

Meanwhile, Non-Patent Document 1 proposes a method capable of adequately balancing a parasitic inductance and a capacitance resulted from a wiring pattern of a printed circuit board as a method of suppressing high frequency current (common mode current) which is a main cause of the radiation and flows through the power-supply wiring/ground (GND) wiring in the same phase. An outline of this method is illustrated in FIG. 12.

FIG. 12 is a schematic diagram illustrating a generation state of a common mode current in an electronic device. As illustrated in an upper part of FIG. 12, the electronic device is constituted of: a circuit board 201 on which a semiconductor device 10 is mounted; a power-supply cable 202; a power supply 203; and a reference GND 101. A drawing illustrated in a lower part of FIG. 12 is that each unit of this component circuit is made to be an equivalent circuit.

The circuit board 201 is represented by an equivalent circuit 501, the power-supply cable 202 is represented by an equivalent circuit 502, and the power supply 203 is represented by an equivalent circuit 503. An inside the equivalent circuit 501 is illustrated with: an equivalent circuit 510 representing the semiconductor device 10 having a noise source 500; parasitic capacitances 531 and 532 for the reference GND 101, which a power-supply wiring pattern 521 and a GND wiring pattern 522 on the circuit board 201 have, respectively; and parasitic inductances. Further, the equivalent circuit 502 representing the power-supply cable 202 and the equivalent circuit 503 representing the power supply 203 are similarly constituted of: parasitic capacitances for the reference GND 101; parasitic inductances; and parasitic capacitances between the power-supply wiring and the GND wiring.

In the equivalent circuits of this component circuit, two noise current loops exist. The noise current leaked from the semiconductor device 10 forms a power-supply side noise current loop 402 flowing to the reference GND 101 through the parasitic capacitance 531 of the power-supply wiring pattern 521 on the circuit board 201, and a GND side noise current loop 403 flowing to the reference GND 101 through the parasitic capacitance 532 of the GND wiring pattern 522 on the circuit board 201. The common mode current which is the high frequency current flowing through the power-supply wiring/GND wiring in the same phase is generated by a difference between these two noise currents.

A reason why the difference is generated between the two noise currents is that there is a difference in impedance between the two noise current loops. In order to reduce the common mode current, it is important to control the parasitic capacitances of the noise current loops and the parasitic inductances of the board wiring patterns so that the impedances of both of the noise current loops are matched with each other. This matching is referred to as a balancing of impedances. Conversely, a state that there is the difference in impedance is referred to as an unbalancing of impedances. In Non-Patent Document 1, the wiring pattern on the circuit board is changed to control a value of the parasitic capacitance for the balancing of impedances, so that the common mode current is suppressed.

Also, as another method of suppressing the common mode current, Patent Document 3 proposes a technique of attenuating a level of the common mode current by providing a hollow portion in a ground layer so as to position below a communication line arranged on a printed wiring board, generating two magnetic fluxes having reverse directions to each other by two loop currents flowing close to the hollow portion, and canceling these two magnetic fluxes with each other.

Patent Document 1: Japanese Patent Application Laid-Open Publication No. 2001-119110

Patent Document 2: Japanese Patent Application Laid-Open Publication No. H11-220056

Patent Document 3: Japanese Patent Application Laid-Open Publication No. 2000-307205

Non-Patent Document 1: IEICE (The Institute of Electronics, Information and Communication Engineers), Transactions on Electronics, Vol. J89-C, No. 11, pp. 854-865

### DISCLOSURE OF THE INVENTION

### Problems to be Solved by the Invention

The patent documents 1 and 2 propose structures of preventing propagation of the high frequency current from the semiconductor device to the circuit board. By the above-described two methods, the propagation of the high frequency current to the two loops (differential mode current) can be suppressed. However, the high frequency current (common mode current) which is the main cause of the radiation and flows through the power-supply wiring/ground (GND) wiring in the same phase cannot be effectively suppressed.

Further, in Non-Patent Document 1, a method of suppressing the unbalancing of impedances of the circuit board to suppress the common mode current is described. However, in the method of the Non-Patent Document 1, the balancing is required in whole system including the semiconductor device and the circuit board. Therefore, impedance adjustment is required in each layout of the circuit board, and this may result in high cost or spending time and effort for designing. In addition, a technique described in Patent Document 3 suppresses the common mode current in the circuit board by using a structure of the circuit board.

Accordingly, a preferred aim of the present invention is to provide a semiconductor device in which the noise current can be reduced without depending on the mounting layout of the circuit board by matching impedances of the power-supply wiring/GND wiring inside the semiconductor device to suppress the common mode current.

The above and other preferred aims and novel characteristics of the present invention will be apparent from the description of the present specification and the accompanying drawings.

### Means for Solving the Problems

The typical ones of the inventions disclosed in the present application will be briefly described as follows.

In a semiconductor device according to a typical embodiment of the present invention including: a package board; a semiconductor chip mounted on the package board; a first wiring for supplying a first power supply potential to the semiconductor chip; and a second wiring for supplying a second power supply potential lower than the first power supply potential to the semiconductor chip, the semiconductor device includes an conductive plate having a third potential different from the first and second power supply potentials, and further includes at least one of a first element arranged on a path of the first wiring for adjusting impedances of the first wiring and the second wiring and a second element arranged on a path of the second wiring for adjusting impedances of the first wiring and the second wiring.

### EFFECTS OF THE INVENTION

The effects obtained by typical aspects of the present invention will be briefly described below.

According to an exemplary embodiment of the present invention, an EMI of a semiconductor device can be suppressed without depending on a wiring state of an external circuit board by balancing an unbalancing of impedances of the semiconductor device only inside the semiconductor device.

### BRIEF DESCRIPTIONS OF THE DRAWINGS

FIG. 1 is a view illustrating a configuration example of a semiconductor device according to a first embodiment of the present invention;

FIG. 2 is another view illustrating the configuration example of the semiconductor device according to the first embodiment of the present invention;

FIG. 3 is a diagram illustrating an approximate equivalent circuit of the semiconductor device according to the first embodiment of the present invention;

FIG. 4 is a diagram illustrating a further-approximate equivalent circuit of the equivalent circuit of the semiconductor device according to the first embodiment of the present invention;

FIG. 5 is a diagram illustrating a generation state of a common mode current when a semiconductor device not having a conductive plate according to the first embodiment of the present invention is mounted on a circuit board;

FIG. 6 is a diagram illustrating a generation state of a common mode current when a semiconductor device having the conductive plate according to the first embodiment of the present invention is mounted on the circuit board;

FIG. 7 is a view illustrating a configuration example of a semiconductor device according to a second embodiment of the present invention;

FIG. 8 is a view illustrating a configuration example of a semiconductor device according to a third embodiment of the present invention;

FIG. 9 is a diagram illustrating an equivalent circuit of the semiconductor device according to the third embodiment of the present invention;

FIG. 10 is a view illustrating a configuration example of a semiconductor device according to a fourth embodiment of the present invention;

FIG. 11 is a diagram illustrating an equivalent circuit of the semiconductor device according to the fourth embodiment of the present invention;

FIG. 12 is a schematic diagram illustrating a generation state of a common mode current in an electronic device;

FIG. 13 is a diagram illustrating a configuration of a measuring system for measuring the generation state of the common mode current;

FIG. 14 is a view illustrating a mounting example of a semiconductor device according to a fifth embodiment of the present invention;

FIG. 15 is a view illustrating a mounting example of a first layer of the semiconductor device according to the fifth embodiment of the present invention;

FIG. 16 is a view illustrating a mounting example of a second layer of the semiconductor device according to the fifth embodiment of the present invention;

FIG. 17 is a view illustrating a mounting example of a third layer of the semiconductor device according to the fifth embodiment of the present invention;

FIG. 18 is a view illustrating a configuration example of a semiconductor device according to a sixth embodiment of the present invention;

FIG. 19 is a diagram illustrating an equivalent circuit of the semiconductor device according to the sixth embodiment of the present invention;

FIG. 20 is a view illustrating a configuration example of a semiconductor device according to a seventh embodiment of the present invention;

FIG. 21 is a diagram illustrating an equivalent circuit of the semiconductor device according to the seventh embodiment of the present invention;

FIG. 22 is a view illustrating a configuration example of a semiconductor device according to an eighth embodiment of the present invention;

FIG. 23 is a view illustrating a configuration example of a semiconductor device according to a ninth embodiment of the present invention;

FIG. 24 is a diagram illustrating a generation state of a common mode current 401 when a semiconductor device according to the first embodiment of the present invention is mounted on the circuit board; and

FIG. 25 is a diagram illustrating an allowable error of a ratio of impedance multiplications when the semiconductor device according to the first embodiment of the present invention is mounted on the circuit board.

### BEST MODE FOR CARRYING OUT THE INVENTION

Hereinafter, embodiments of the present invention will be described in detail with reference to the accompanying drawings. Note that components having the same function are denoted by the same reference symbols throughout the drawings for describing the embodiment, and the repetitive description thereof will be omitted.

### First Embodiment

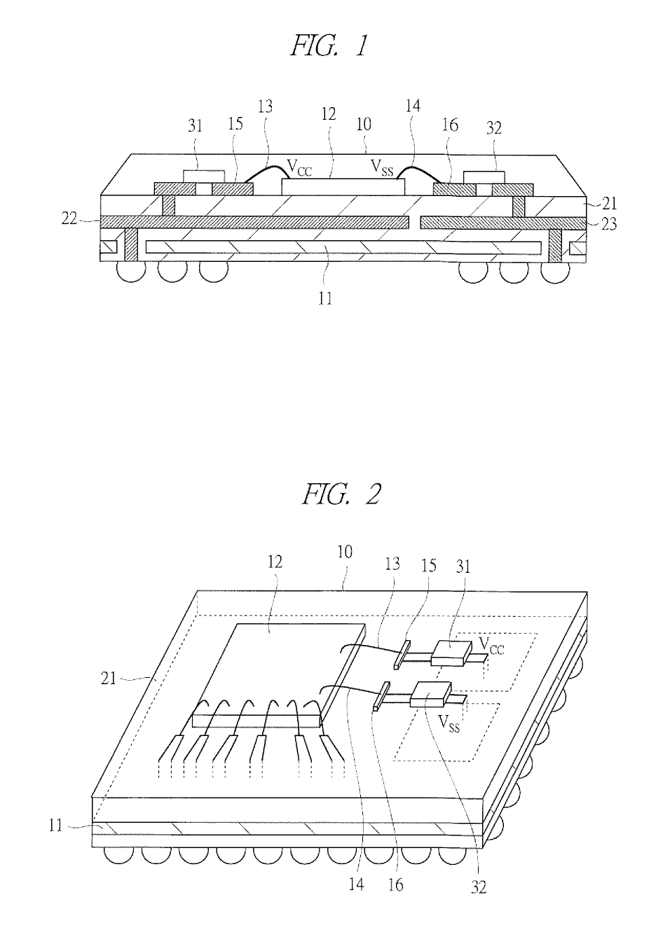

Hereinafter, a semiconductor device according to a first embodiment of the present invention will be described. FIGS. 1 and 2 are views illustrating the configuration examples of the semiconductor device according to the present embodiment.

A power-supply terminal of a semiconductor chip 12 is connected to a power-supply wiring 15 formed in a wiring layer through a wire 13. The power-supply wiring 15 is connected to a power-supply layer 22 through an impedance adjusting element 31. Also, a GND terminal of the semiconductor chip 12 is similarly connected to a GND wiring 16 formed in the wiring layer through a wire 14. The GND wiring 16 is connected to a GND layer 23 through an impedance adjusting element 32. A dielectric material 21 is filled between respective layers of a package board.

A conductive plate 11 is arranged on a bottom layer of the semiconductor device 10. The conductive plate 11 has a potential different from those of the power-supply wiring 15/GND wiring 16 inside the semiconductor device 10 for a reference GND 101, and generates a parasitic capacitance to the power-supply wiring 15/GND wiring 16. The conductive plate 11 is provided directly below the power-supply wiring 15/GND wiring 16 and on a contact surface side with the circuit board of the semiconductor device 10.

Although the conductive plate 11 is provided as described above in the present embodiment, the conductive plate 11 may have an arbitrary size as long as it generates the parasitic capacitance to the power-supply wiring 15/GND wiring 16. Further, although the conductive plate 11 is preferably provided on the contact surface side with the circuit board of the semiconductor device 10, the conductive plate may be provided on an arbitrary position as long as it generates the parasitic capacitance to the power-supply wiring 15/GND wiring 16 inside the semiconductor device 10.

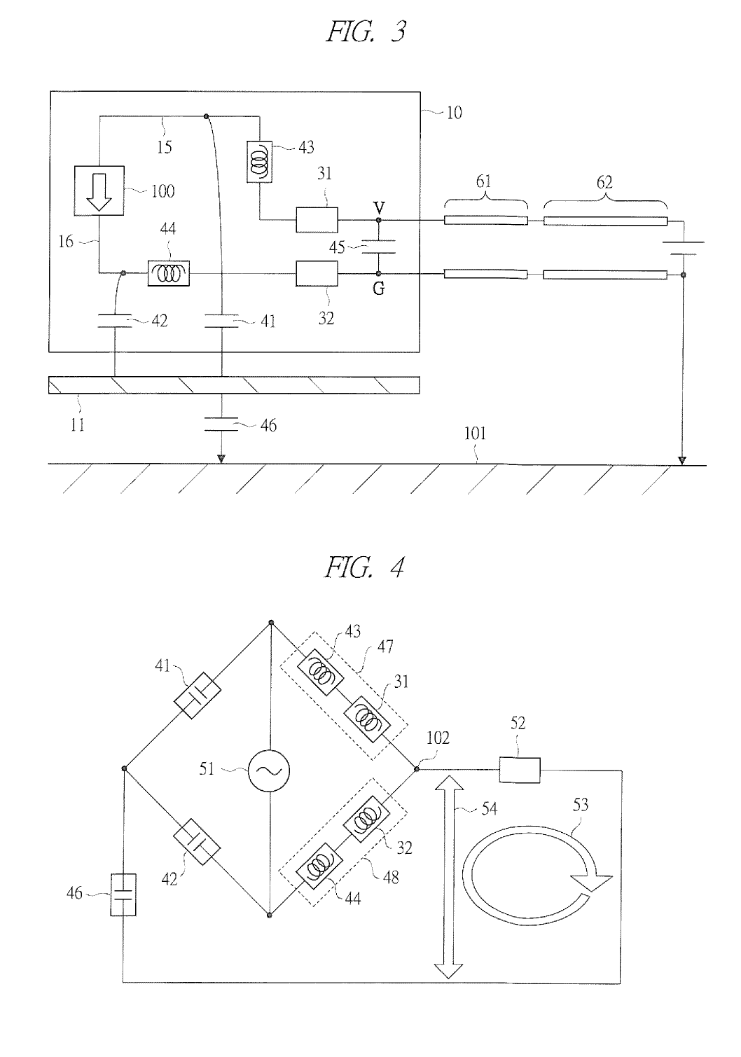

FIG. 3 is a diagram illustrating an approximate equivalent circuit of the semiconductor device 10 according to the present embodiment. In FIG. 3, the equivalent circuit is constituted of the semiconductor device 10, a circuit board 61 on which the semiconductor device 10 is mounted, and a power-supply cable 62. When the semiconductor chip 12 illustrated in FIGS. 1 and 2 is operated, a through current 100 flows to the semiconductor device 10. In the power-supply wiring 15 and the GND wiring 16 inside the semiconductor device 10, parasitic inductances 43 and 44 are generated, respectively. Further, parasitic capacitances 41 and 42 are generated between the power-supply wiring 15/GND wiring 16 and the conductive plate 11, respectively.

A parasitic capacitance 45 is a parasitic capacitance between the power supply wiring 15 and the GND wiring 16, and a parasitic capacitance 46 is a parasitic capacitance between the conductive plate 11 and the reference GND 101. Although the parasitic capacitance 45 exists between V and G in FIG. 3, a bypass capacitor may be mounted between the V and G. At this time, a value of impedance between the V and G is adjusted to be sufficiently smaller than those of wiring impedances of the impedance adjusting elements 31 and 32 and the parasitic inductances 43 and 44, and the same potential is provided between the V and G in high frequency.

FIG. 4 is a diagram illustrating a further-approximate equivalent circuit of the equivalent circuit illustrated in FIG. 3. In FIG. 4, a connection point 102 is a point at which the semiconductor device 10 and the circuit board 61 are connected to each other, and further, a common mode impedance 52 of an impedance between the circuit board 61 and the power supply cable 62, a common mode current 53, and a common mode voltage 54 are illustrated. In this circuit, a condition of suppressing the common mode current 53 is derived.

The impedances of the parasitic capacitances 41 and 42 between the conductive plate 11 and the power-supply wiring 15/GND wiring 16 in the circuit of FIG. 4 are taken as Z_{Cv} and Z_{Cg}, respectively. Further, synthetic impedances 47 and 48 which are impedance values obtained by synthesizing values of the impedance adjusting elements 31 and 32 with the parasitic inductances 43 and 44 of the power-supply wiring 15/GND wiring 16 are taken as Z_{Lv} and Z_{Lg}, respectively. Still further, the common mode impedance 52 which is the impedance between the circuit board and the power-supply cable is taken as Z_{C}, the common mode voltage 54 is taken as V_{C}, and a voltage of the noise source 51 is taken as V_{d}. At this time, the common mode voltage 54 can be expressed by the following formula.

$$\begin{matrix}[ Formula 1 ] & \\ {V}_{C} = \frac{( {Z}_{Lg} {Z}_{Cv} - {Z}_{Cg} {Z}_{Lv} )}{( {Z}_{Cv} + {Z}_{Cg} ) ( {Z}_{Lv} + {Z}_{Lg} )} {V}_{d} & Formula 1\end{matrix}$$

The common mode current 53 is proportional to the common mode voltage 54. Therefore, a condition for suppressing the common mode current 53 can be obtained as the following formula.

[Formula 2]

Z_{Cv}Z_{Lg}=Z_{Cg}Z_{Lv} Formula 2

This formula similarly expresses a condition of balancing a bridge circuit of FIG. 4. Here, when the parasitic capacitances 41 and 42 are taken as Cᵥ and C_{g}, the parasitic inductances 43 and 44 of the power-supply wiring 15/GND wiring 16 are taken as Lᵥ and L_{g}, and impedance adjusting elements 31 and 32 are taken as Lᵥ′ and L_{g}′, the following formula can be obtained.

[Formula 3]

C_{g}(L_{g}+L_{g}′=Cᵥ(Lᵥ+Lᵥ′) Formula 3

By adjusting the impedance adjusting elements 31 and 32 so as to satisfy this condition, it is found out that the common mode current 53 can be suppressed.

As a comparison example for the semiconductor device 10 according to the present embodiment, in the configuration of the semiconductor device 10 illustrated in FIG. 1, the generation state of the common mode current when the semiconductor device 10 not having the conductive plate 11 is mounted on the circuit board and the generation state of the common mode current when the semiconductor device 10 having the conductive plate 11 is mounted on the circuit board are illustrated.

FIG. 13 is a view illustrating a configuration of a measuring system for measuring the generation states of the common mode currents. In FIG. 13, the measuring system is constituted of: a circuit board 201 on which the semiconductor device 10 is mounted; a power-supply cable 202; a dummy load circuit 204; and a power supply 203. The power-supply cable 202 has a length of 1500 mm from the circuit board 201, and is positioned at a height of 50 mm from the reference GND 101. Also, the circuit board 201 is positioned at a height of 50 mm from the reference GND 101. A current probe 302 is fixed at a position which is 50 mm away from the circuit board 201.

The circuit board 201 is operated, and a common mode current 401 flowing through the power-supply cable 202 is measured by using the current probe 302 and a spectrum analyzer 301. Inductance elements are used for the impedance adjusting elements 31 and 32 in an upper portion of the semiconductor device 10 in FIG. 1, and a value of the impedance adjusting element 32 on the GND terminal side is fixed at 10 nH, and a variation of the common mode current 401 when a value of the impedance adjusting element 31 on the power-supply terminal side is changed from 1 nH to 100 nH is measured.

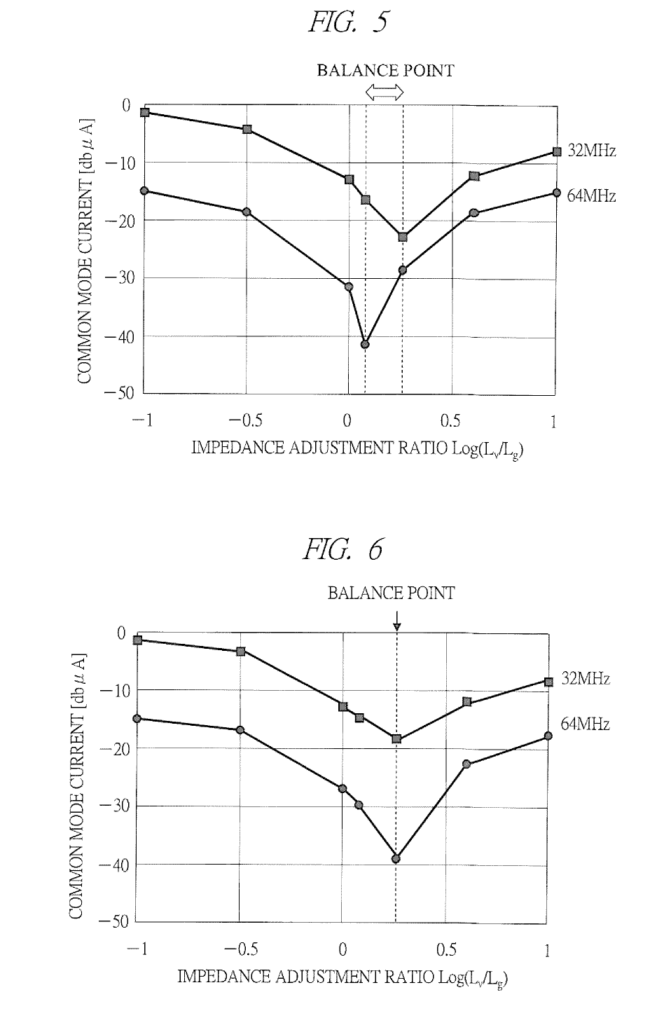

FIG. 5 is a diagram illustrating the generation state of the common mode current 401 when the semiconductor device 10 not having the conductive plate 11 is mounted on the circuit board 201, and FIG. 6 is a diagram illustrating the generation state of the common mode current 401 when the semiconductor device 10 having the conductive plate 11 is mounted on the circuit board 201. When the value of the impedance adjusting element 31 on the power-supply terminal side is taken as L_{g} and the value of the impedance adjusting element 32 on the GND terminal side is taken as Lᵥ, a ratio of L_{g} and Lᵥ is set on a horizontal axis as an impedance adjusting ratio and the common code current 401 is set on a vertical axis for comparison.

From results of FIGS. 5 and 6, it is found out that the common mode current 401 can be suppressed by adjusting the impedances by the impedance adjusting elements 31 and 32. In FIG. 5, since the parasitic capacitances 41 and 42 illustrated in FIG. 3 are not uniquely decided because of being affected by the wiring pattern of the circuit board 201 on which the semiconductor device 10 is mounted, a balance point at which the common mode current 401 is minimized varies every frequency. Therefore, an effect of suppressing the common mode current 401 is varied depending on a layout of the circuit board 201. On the other hand, in the semiconductor device 10 having the conductive plate 11, the balance point is uniquely decided as illustrated in FIG. 6, and the common mode current 401 can be suppressed without being affected by the circuit board 201.

As described above, in the semiconductor device 10 having the conductive plate 11 according to the present embodiment, the common mode current can be suppressed without being affected by the wiring pattern of the circuit board 201 on which the semiconductor device 10 is mounted, by adjusting and balancing the impedances only inside the semiconductor device 10 with using the impedance adjusting elements 31 and 32.

### Second Embodiment

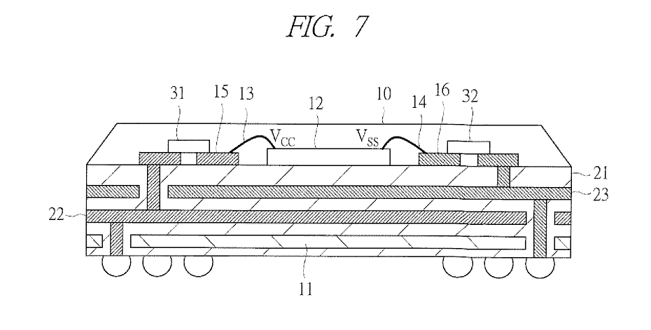

Hereinafter, a semiconductor device according to a second embodiment of the present invention will be described. FIG. 7 is a view illustrating a configuration example of the semiconductor device according to the present embodiment. The semiconductor device 10 according to the present embodiment is an example of a case that the power-supply layer 22 and the GND layer 23 in the configuration of the semiconductor device 10 illustrated in FIG. 1 are not provided on the same-surface layer but provided on each different layer.

Whether the power-supply wiring 15/GND wiring 16 are provided on the same surface or multi-layered, the semiconductor device 10 can be similarly dealt as the equivalent circuit illustrated in FIG. 3, and similarly to the first embodiment, the common mode current can be suppressed by adjusting impedances by using impedance adjusting elements 31 and 32.

### Third Embodiment

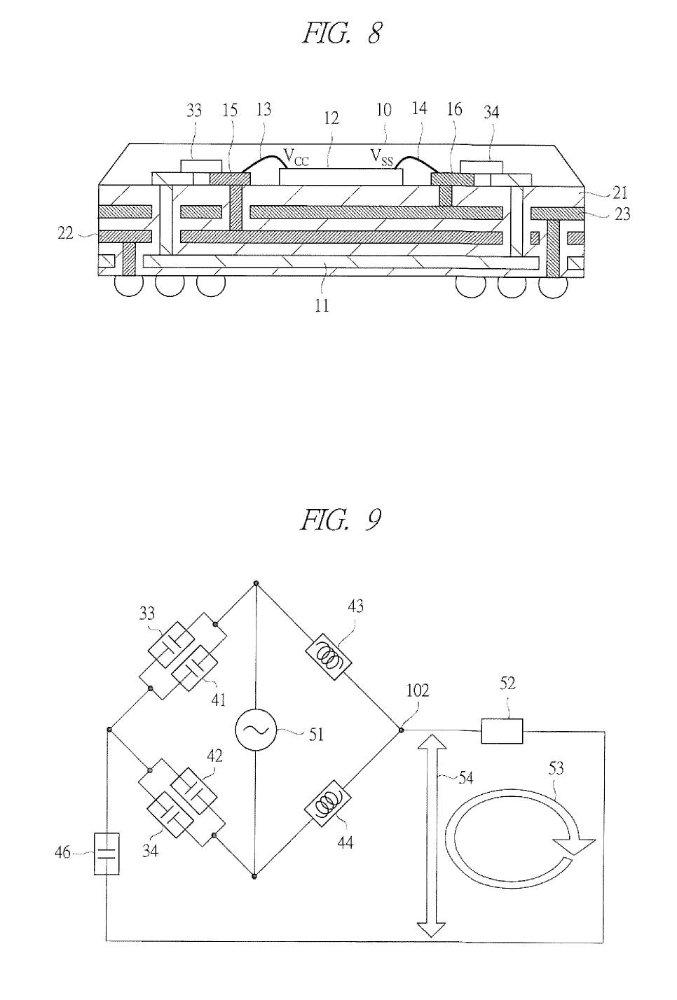

Hereinafter, a semiconductor device according to a third embodiment of the present invention will be described. FIG. 8 is a view illustrating a configuration example of the semiconductor device according to the present embodiment. A power-supply terminal of a semiconductor chip 12 is connected to a power-supply wiring 15 formed in a wiring layer through a wire 13. The power-supply wiring 15 is connected to a power-supply layer 22 and is connected to a conductive plate 11 through an impedance adjusting element 33. Also, a GND terminal of the semiconductor chip 12 is similarly connected to a GND wiring 16 through a wire 14. The GND wiring 16 is connected to a GND layer 23 and is connected to the conductive plate 11 through an impedance adjusting element 34. A dielectric material 21 is filled between respective layers of a package board.

The conductive plate 11 is arranged on a bottom layer of the semiconductor device 10. The conductive plate 11 has a potential different from those of the power-supply wiring 15/GND wiring 16 inside the semiconductor device 10 for a reference GND 101, and generates a parasitic capacitance to the power-supply wiring 15/GND wiring 16. Similarly to the first embodiment, the conductive plate 11 may have an arbitrary size as long as it generates the parasitic capacitance to the power-supply wiring 15/GND wiring 16. Further, although the conductive plate 11 is preferably provided on a contact surface side with the circuit board of the semiconductor device 10, the conductive plate may be provided on an arbitrary position as long as it generates the parasitic capacitance to the power-supply wiring 15/GND wiring 16 inside the semiconductor device 10.

FIG. 9 is a diagram illustrating an equivalent circuit of the semiconductor device 10 according to the present embodiment. The equivalent circuit of the power-supply wiring 15/GND wiring 16 of the semiconductor device 10 is illustrated with: impedance adjusting elements 33 and 34 provided in the power-supply wiring 15/GND wiring 16, respectively; a parasitic capacitance 41 generated between the power-supply wiring 15 and the conductive plate 11; a parasitic capacitance 42 generated between the GND wiring 16 and the conductive plate 11; a parasitic inductance 43 of the power-supply wiring 15; and a parasitic inductance 44 of the GND wiring 16.

In order to suppress a common mode current 53 in FIG. 9, only the generation of the common mode voltage 54 is required to be suppressed. In the equivalent circuit illustrated in FIG. 9, if a bridge circuit constituted of a noise source 51, the parasitic capacitances 41 and 42, the parasitic inductances 43 and 44, and the impedance adjusting elements 33 and 34 is balanced, the generation of the common mode voltage 54 can be suppressed. At this time, since the noise source 51, the parasitic capacitances 41 and 42, and the parasitic inductances 43 and 44 are predetermined by the structure of the semiconductor device 10, the bridge circuit can be balanced by adjusting the impedance adjusting elements 33 and 34.

That is, when values obtained by synthesizing the impedances of the impedance adjusting elements 33 and 34 with the parasitic capacitances 41 and 42 in the circuit of FIG. 9 are taken as Z_{Cv} and Z_{Cg}, and further, the impedances of the parasitic inductances 43 and 44 are taken as Z_{Lv} and Z_{Lg}, respectively, a condition of balancing the bridge circuit is similarly expressed as Formula 2 in the first embodiment. When the parasitic capacitances 41 and 42 are taken as Cᵥ and C_{g}, the impedance adjusting elements 33 and 34 are taken as Cᵥ′ and C_{g}′, and the parasitic inductances 43 and 44 are taken as Lᵥ and L_{g}, respectively, the following formula can be obtained.

[Formula 4]

(C_{g}+C_{g}′)L_{g}=(Cᵥ+Cᵥ′)Lᵥ Formula 4

It is found out that, by adjusting the impedance adjusting elements 33 and 34 so as to satisfy this condition, the common mode current 53 can be suppressed. At this time, note that capacitive adjusting elements are used for the impedance adjusting elements 33 and 34 for preventing short circuit between the conductive plate 11 and the power-supply wiring 15/GND wiring 16 in a low frequency region.

### Fourth Embodiment

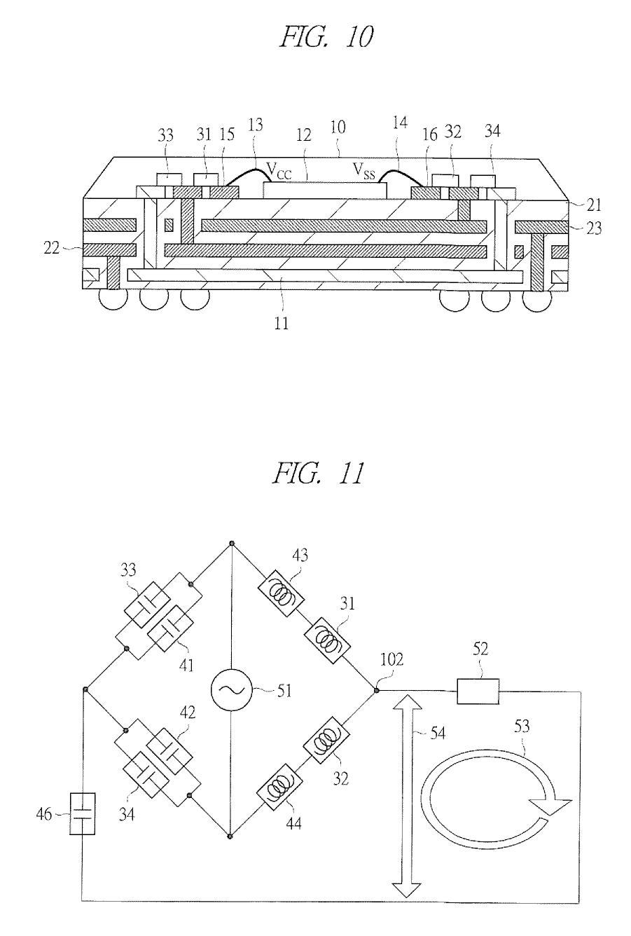

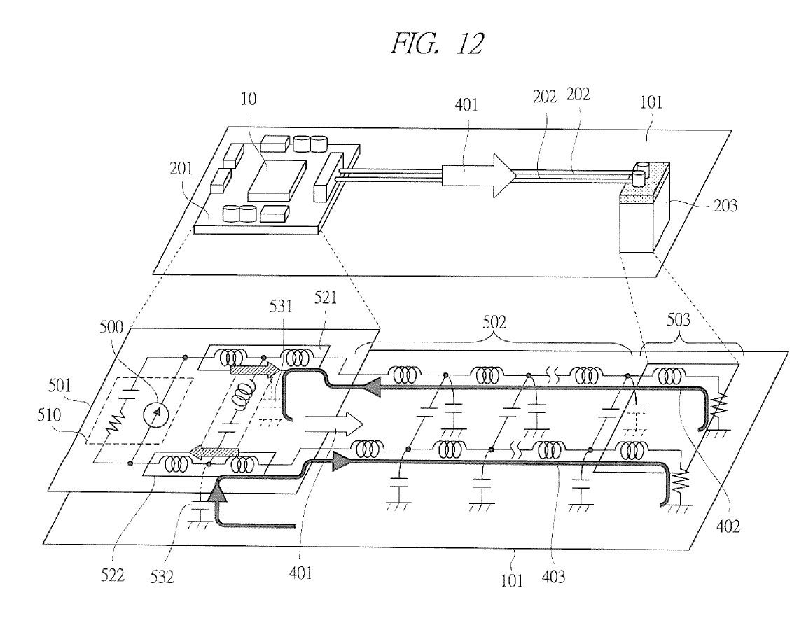

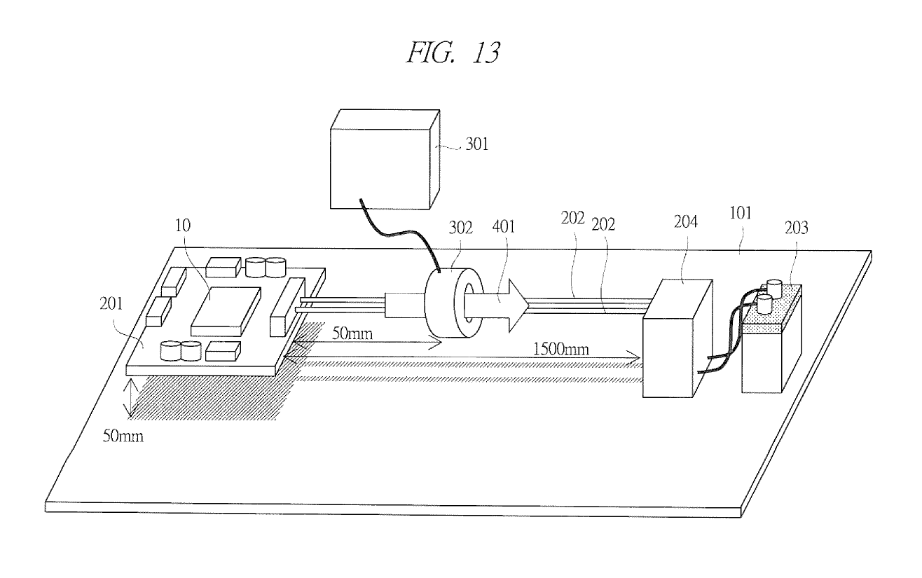

Hereinafter, a semiconductor device according to a fourth embodiment of the present invention will be described. FIG. 10 is a view illustrating a configuration example of the semiconductor device according to the present embodiment. A power-supply terminal of a semiconductor chip 12 is connected to a power-supply wiring 15 formed in a wiring layer through a wire 13. The power-supply wiring 15 is connected to a power-supply layer 22 through an impedance adjusting element 31 and is connected to a conductive plate 11 through an impedance adjusting element 33. Also, a GND terminal of the semiconductor chip 12 is similarly connected to a GND wiring 16 through a wire 14. The GND wiring 16 is connected to a GND layer 23 through an impedance adjusting element 32 and is connected to the conductive plate 11 through an impedance adjusting element 34. A dielectric material 21 is filled between respective layers of a package board.

The conductive plate 11 is arranged on a bottom layer of the semiconductor device 10. The conductive plate 11 has a potential different from those of the power-supply wiring 15/GND wiring 16 inside the semiconductor device 10 for a reference GND 101, and generates a parasitic capacitance to the power-supply wiring 15/GND wiring 16. Similarly to the first embodiment, the conductive plate 11 may have an arbitrary size as long as it generates the parasitic capacitance to the power-supply wiring 15/GND wiring 16. Further, although the conductive plate 11 is preferably provided on a contact surface side with the circuit board of the semiconductor device 10, the conductive plate may be provided on an arbitrary position as long as it generates the parasitic capacitance to the power-supply wiring 15/GND wiring 16 inside the semiconductor device 10.

FIG. 11 is a diagram illustrating an equivalent circuit of the semiconductor device 10 according to the present embodiment. The equivalent circuit of the power-supply wiring 15/GND wiring 16 of the semiconductor device 10 is illustrated with: impedance adjusting elements 31 and 32 and impedance adjusting elements 33 and 34 provided in the power-supply wiring 15/GND wiring 16, respectively; a parasitic capacitance 41 generated between the power-supply wiring 15 and the conductive plate 11; a parasitic capacitance 42 generated between the GND wiring 16 and the conductive plate 11; a parasitic inductance 43 of the power-supply wiring 15; and a parasitic inductance 44 of the GND wiring 16.

In order to suppress a common mode current 53 in FIG. 11, it is only required to suppress the generation of the common mode voltage 54. In the equivalent circuit illustrated in FIG. 11, if a bridge circuit constituted of a noise source 51, the parasitic capacitances 41 and 42, the parasitic inductances 43 and 44, and the impedance adjusting elements 31, 32, 33, and 34 is balanced, the generation of the common mode voltage 54 can be suppressed. At this time, each value of the noise source 51, the parasitic capacitances 41 and 42, and the parasitic inductances 43 and 44 is previously determined by the structure of the semiconductor device 10, and therefore, the bridge circuit can be balanced by adjusting the impedance adjusting elements 31, 32, 33, and 34.

That is, when values obtained by synthesizing the impedances of the impedance adjusting elements 33 and 34 with the parasitic capacitances 41 and 42 in the circuit of FIG. 11 are taken as Z_{Cv} and Z_{Cg}, and further, impedance values obtained by synthesizing the parasitic inductances 43 and 44 with the impedance adjusting elements 31 and 32 are taken as Z_{Lv} and Z_{Lg}, respectively, a condition of balancing the bridge circuit is similarly expressed as Formula 2 in the first embodiment. When the parasitic capacitances 41 and 42 are taken as Cᵥ and C_{g}, the impedance adjusting elements 33 and 34 are taken as Cᵥ′ and C_{g}′, the parasitic inductances 43 and 44 are taken as Lᵥ and L_{g}, and the impedance adjusting elements 31 and 32 are taken as Lᵥ′ and L_{g}′, respectively, the following formula can be obtained.

[Formula 5]

(C_{g}+C_{g}′)(L_{g}+L_{g}′)=(Cᵥ+Cᵥ′)(Lᵥ+L_{g}′) Formula 5

It is found out that the common mode current 53 can be suppressed by adjusting the impedance adjusting elements 31, 32, 33, and 34 so as to satisfy this condition. Note that a capacitive adjusting element is used for the impedance adjusting elements 33 and 34 at this time for preventing short circuit between the conductive plate 11 and the power-supply wiring 15/GND wiring 16 in a low frequency region.

As described above, in the semiconductor device 10 having the conductive plate 11 as described in the examples of the first to fourth embodiments, the impedances are adjusted and balanced only inside the semiconductor device 10 by using the impedance adjusting elements 31, 32, 33, and 34, so that the common mode current can be suppressed without being affected by the wiring pattern of the circuit board 201 on which the semiconductor device 10 is mounted, and the noise current can be reduced.

### Fifth Embodiment

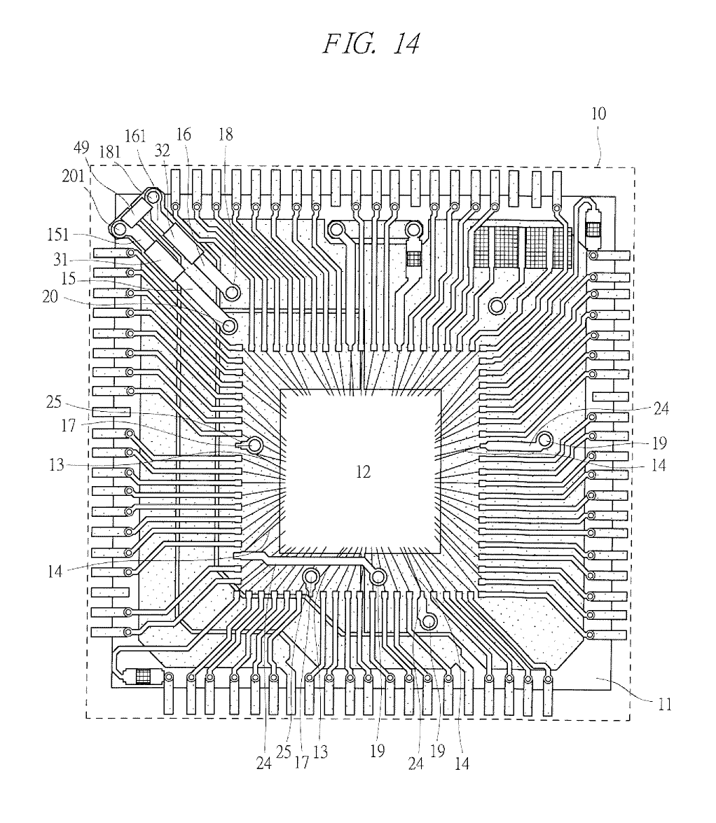

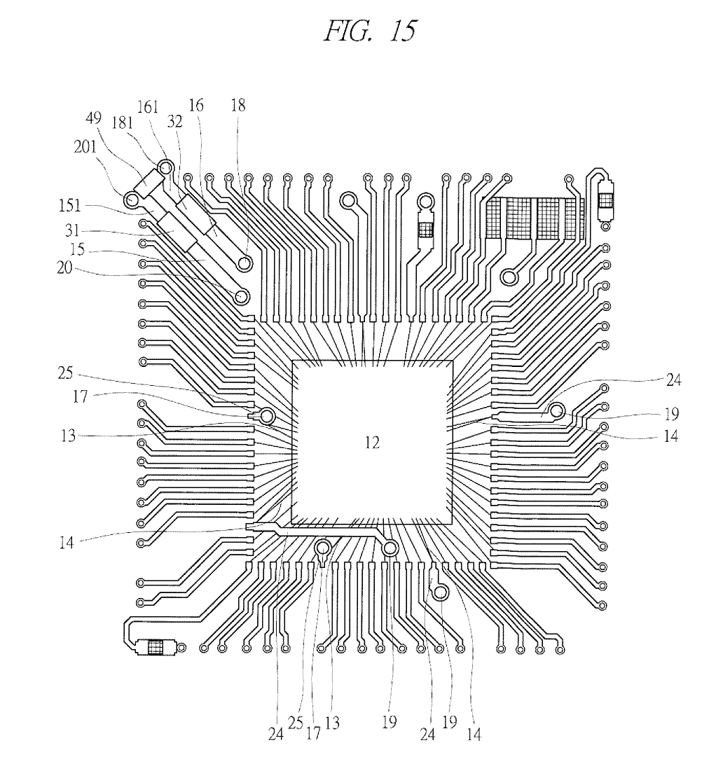

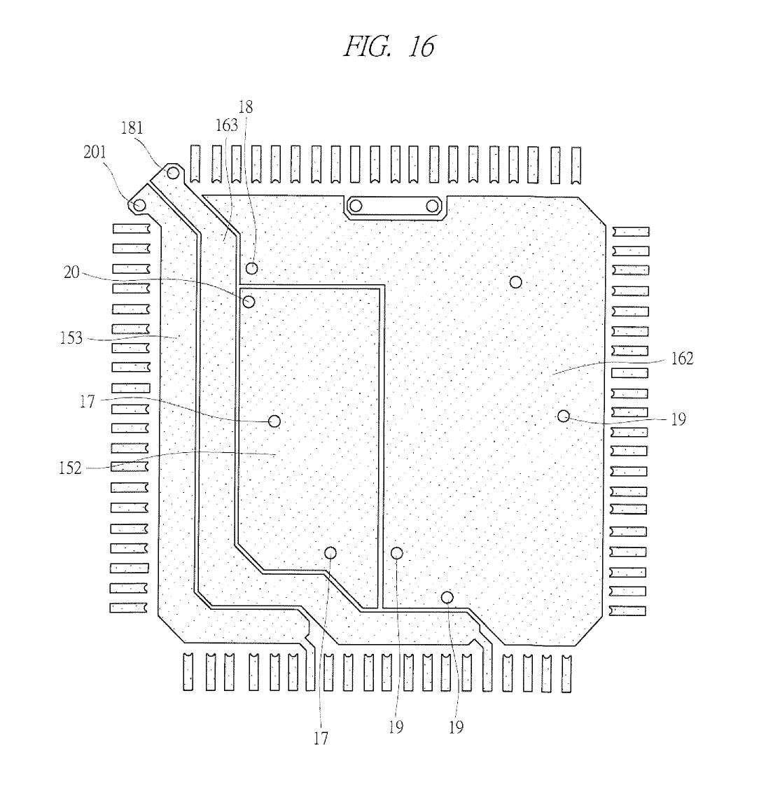

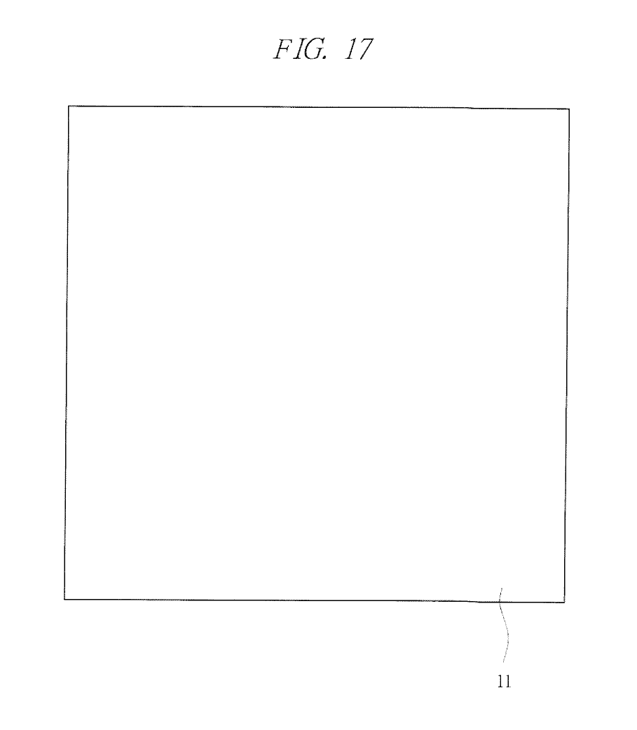

Hereinafter, a semiconductor device according to a fifth embodiment of the present invention will be described. FIGS. 14 to 17 are views each illustrating a mounting example of the semiconductor device according to the present embodiment. FIG. 14 is a view illustrating amounting example of the semiconductor device 10, and FIGS. 15 to 17 are views illustrating mounting examples of first to third layers of the semiconductor device 10, respectively.

A power-supply terminal of a semiconductor chip 12 is connected to a power-supply wiring 25 formed in a wiring layer in the first layer through a wire 13. The power-supply wiring 25 is connected to a power-supply wiring 152 in the second layer through a via 17. Further, the power-supply wiring 152 is connected to a power-supply wiring 15 in the first layer through a via 20, and then, is connected to a power-supply wiring 151 through an impedance adjusting element 31. Still further, the power-supply wiring 151 is connected to a power-supply wiring 153 in the second layer through a via 201.

Also, a GND terminal of the semiconductor chip 12 is similarly connected to a GND wiring 24 formed in a wiring layer in the first layer through a wire 14. The GND wiring 24 is connected to a GND wiring 162 in the second layer through a via 19. Further, the GND wiring 162 is connected to a GND wiring 16 in the first layer through a via 18, and then, is connected to a GND wiring 161 through an impedance adjusting element 32. Still further, the GND wiring 161 is connected to a GND wiring 163 in the second layer through a via 181. Note that the conductive plate 11 is provided in the third layer, and a dielectric material is filled between respective layers.

In this manner, when the power-supply wiring/GND wiring are pulled around so as to be connected to an external power-supply wiring of its package through the impedance adjusting elements 31 and 32, the common mode current can be reduced similarly to the first to the fourth embodiments. Further, as illustrated in the example of the present embodiment, a bypass capacitor 49 may be mounted between the power-supply wiring and the GND wiring.

### Sixth Embodiment

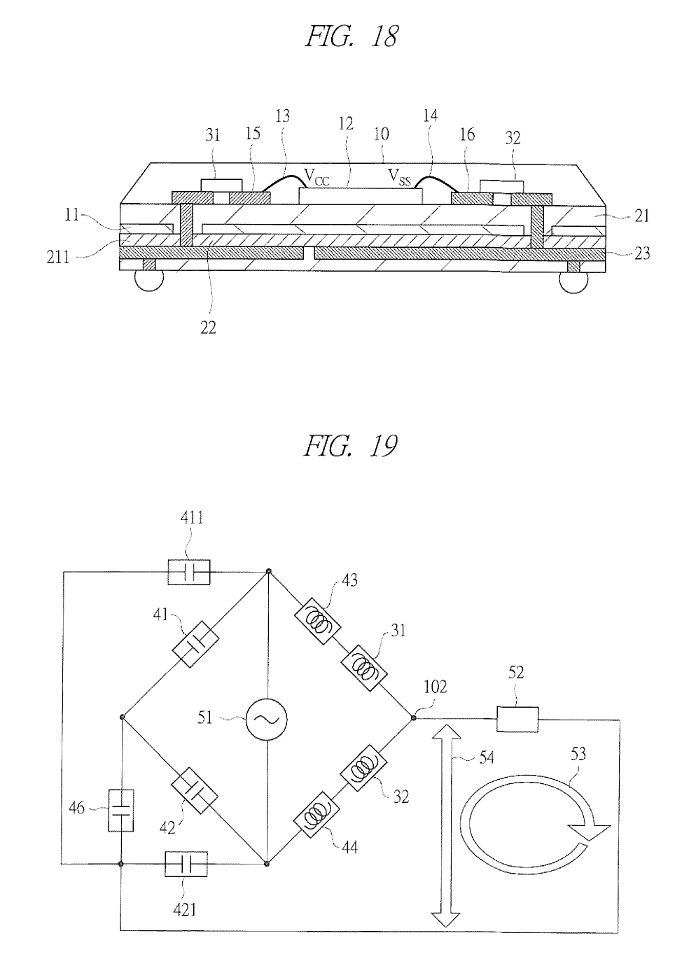

Hereinafter, a semiconductor device according to a sixth embodiment of the present invention will be described. FIG. 18 is a view illustrating a configuration example of the semiconductor device according to the present embodiment. The semiconductor device 10 according to the present embodiment is an example of a case that a conductive plate 11 is arranged not on a contact surface side with a circuit board but between a semiconductor chip 12 and a portion of a power-supply layer 22 and a GND layer 23.

An equivalent circuit at this time is as illustrated in FIG. 19, and a power supply wiring 15/GND wiring 16 on a package board have parasitic capacitances 411 and 421 for a reference GND 101, respectively. However, for example, in order to partially change a dielectric constant inside the package board, by inserting a dielectric material 211, changing a dielectric constant of a dielectric material 21, decreasing a distance between the package boards, or increasing a distance between the package and the reference GND 101 so as to be away from each other, values of parasitic capacitances 41 and 42 for the parasitic capacitances 411 and 421 are increased, so that an influence of the parasitic capacitances 411 and 421 can be reduced. Therefore, the equivalent circuit can be similarly dealt as that of FIG. 4 as described above.

### Seventh Embodiment

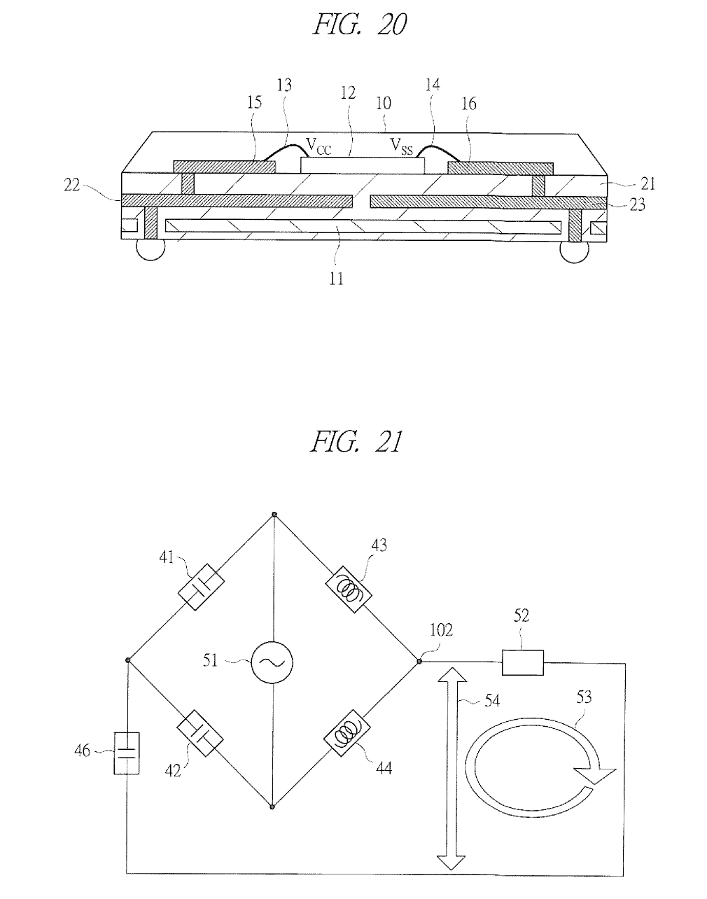

Hereinafter, a semiconductor device according to a seventh embodiment of the present invention will be described. FIG. 20 is a diagram illustrating a configuration example of the semiconductor device according to the present embodiment. The semiconductor device 10 according to the present embodiment is an example of a case that impedance adjusting elements 31 and 32 are not provided. Also, FIG. 21 is a diagram illustrating an equivalent circuit of the semiconductor device 10 according to the present embodiment. The equivalent circuit of the power-supply wiring 15/GND wiring 16 of the semiconductor device 10 is illustrated with: a parasitic capacitance 41 generated between the power-supply wiring 15 and a conductive plate 11; a parasitic capacitance 42 generated between the GND wiring 16 and the conductive plate 11; a parasitic inductance 43 of the power-supply wiring 15; and a parasitic inductance 44 of the GND wiring 16.

Here, as long as values of the parasitic capacitances 41 and 42 generated between the conductive plate 11 and the power supply wiring 15/GND wiring 16 on the package board and the parasitic inductances 43 and 44 are values satisfying Formula 2 described in the first embodiment, the common mode current 53 can be reduced even in the case that the impedance adjusting elements 31 and 32 are not provided.

In order to suppress the common mode current 53 in the equivalent circuit illustrated in FIG. 21, it is only required to suppress the generation of the common mode voltage 54. Here, if a bridge circuit constituted of a noise source 51, the parasitic capacitances 41 and 42, and the parasitic inductances 43 and 44 is balanced, the generation of the common mode voltage 54 can be suppressed. At this time, values of the noise source 51, the parasitic capacitances 41 and 42, and the parasitic inductances 43 and 44 are previously determined by the structure of the semiconductor device 10, and therefore, it is found out that the bridge circuit is designed so as to be balanced in the design of the semiconductor device 10.

That is, when the parasitic capacitances 41 and 42 in the equivalent circuit of FIG. 21 are taken as Z_{Cv} and Z_{Cg}, and further, the parasitic inductances 43 and 44 are taken as Z_{Lv} and Z_{Lg}, respectively, a condition of balancing the bridge circuit is similarly expressed as Formula 2 in the first embodiment. Therefore, when the parasitic capacitances 41 and 42 are taken as Cᵥ and C_{g}, and the parasitic inductances 43 and 44 are taken as Lᵥ and L_{g}, respectively, the following formula can be obtained.

[Formula 6]

CᵥLᵥ=C_{g}L_{g} Formula 6

In this manner, even in the case without the impedance adjusting elements 31 and 32, the common mode current 53 can be reduced by the design as satisfying Formula 6.

### Eighth Embodiment

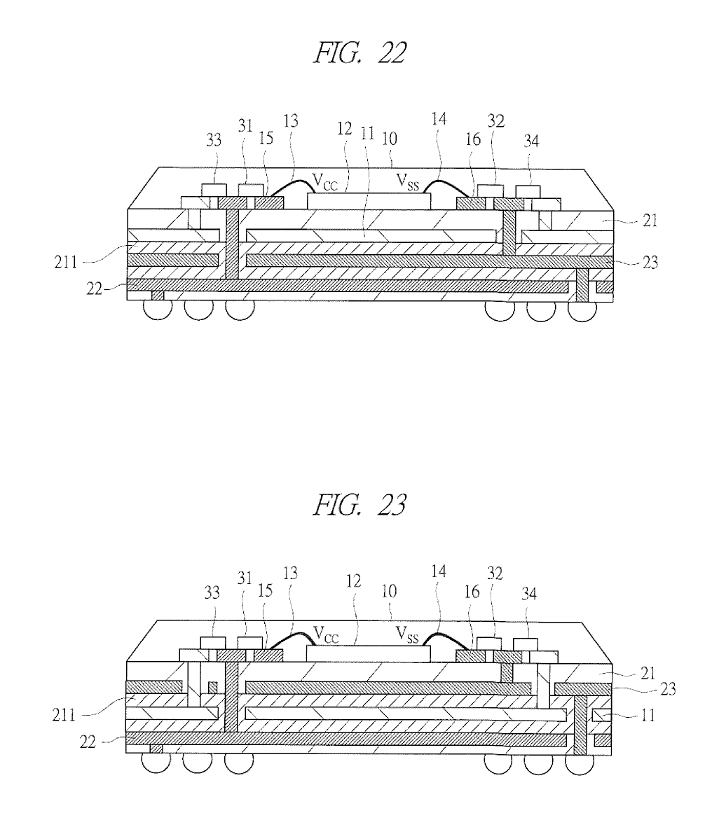

Hereinafter, a semiconductor device according to an eighth embodiment of the present invention will be described. As described in the second embodiment, although a conductive plate 11 is preferably arranged on a circuit board surface side, the conductive plate may be provided on an arbitrary position as long as it generates the parasitic capacitance to a power-supply wiring 15/GND wiring 16. FIG. 22 is a view illustrating a configuration example of the semiconductor device according to the present embodiment. In the semiconductor device 10 according to the present embodiment, the conductive plate 11 is arranged between a semiconductor chip 12 and a power-supply layer 23. In an equivalent circuit of this case, a capacitance is generated to a reference GND 101 as the parasitic capacitances 411 and 421 illustrated in FIG. 19.

However, for example, in order to partially change a dielectric constant inside a package board, by inserting a dielectric material 211, changing a dielectric constant of the dielectric material 21, decreasing a distance between the package boards, or increasing a distance between the package and the reference GND 101 so as to be away from each other, values of parasitic capacitances 41 and 42 for the parasitic capacitances 411 and 421 is increased similarly to the sixth embodiment, so that an influence of the parasitic capacitances 411 and 421 can be reduced. Therefore, the equivalent circuit can be similarly dealt as that of FIG. 11 as described above.

### Ninth Embodiment

Hereinafter, a semiconductor device according to a ninth embodiment of the present invention will be described. As described in the second embodiment, although a conductive plate 11 is preferably arranged on a circuit board surface side, the conductive plate may be provided on an arbitrary position as long as it generates the parasitic capacitance to a power-supply wiring 15/GND wiring 16. FIG. 23 is a view illustrating a configuration example of the semiconductor device according to the present embodiment. In the semiconductor device 10 according to the present embodiment, the conductive plate 11 is arranged between a power-supply layer 22 and a GND layer 23. In an equivalent circuit of this case, a capacitance is generated to a reference GND 101 as the parasitic capacitances 411 and 421 illustrated in FIG. 19.

However, for example, in order to partially change a dielectric constant inside a package board, by inserting a dielectric material 211, changing a dielectric constant of the dielectric material 21, decreasing a distance between the package boards, or increasing a distance between the package and the reference GND 101 so as to be away from each other, values of parasitic capacitances 41 and 42 for the parasitic capacitances 411 and 421 are increased similarly to the sixth embodiment, so that influence of the parasitic capacitances 411 and 421 can be reduced. Therefore, the equivalent circuit can be similarly dealt as that of FIG. 11 as described above.

Note that, in the above-described first to the ninth embodiments, Formula 2 is the one expressing that the common mode current can be reduced if one multiplication of the impedances is equal to the other. However, when a ratio β of the impedance multiplications expressed by the following formula is considered, the reducing effect is large in a range of error of 3% of β.

$$\begin{matrix}[ Formula 7 ] & \\ β = \frac{{Z}_{Cv} {Z}_{Lg}}{{Z}_{Cg} {Z}_{Lv}} & Formula 7\end{matrix}$$

For example, in on-vehicle apparatuses, radiation electromagnetic field is regulated by Class 5 of limits and methods of measurement for radio disturbance characteristics for the protection of on-vehicle receivers (CISPR 25), which is a standard set by International Special Committee on Radio Interference (CISPR). According to the standard, a radiation electromagnetic field which exists in a distance d=1 m away from wire harness such as the power-supply cable 202 connecting between the on-vehicle equipment and the power supply is required to be 12 dB μV/m or smaller. For example, in the measuring system illustrated in FIG. 13, when a value of the common mode current 401 flowing through the power-supply cable 202 having a length L=1.5 m is calculated from this regulated value by the following formula, the value is required to be 0.18 dB μA or smaller in “f=70 MHz”.

$$\begin{matrix}[ Formula 8 ] & \\ E [ dB μ V \text{/} m ] = 6.28 \times {10}^{- 7} \frac{\vert {I}_{C} \vert fL}{d} & Formula 8\end{matrix}$$

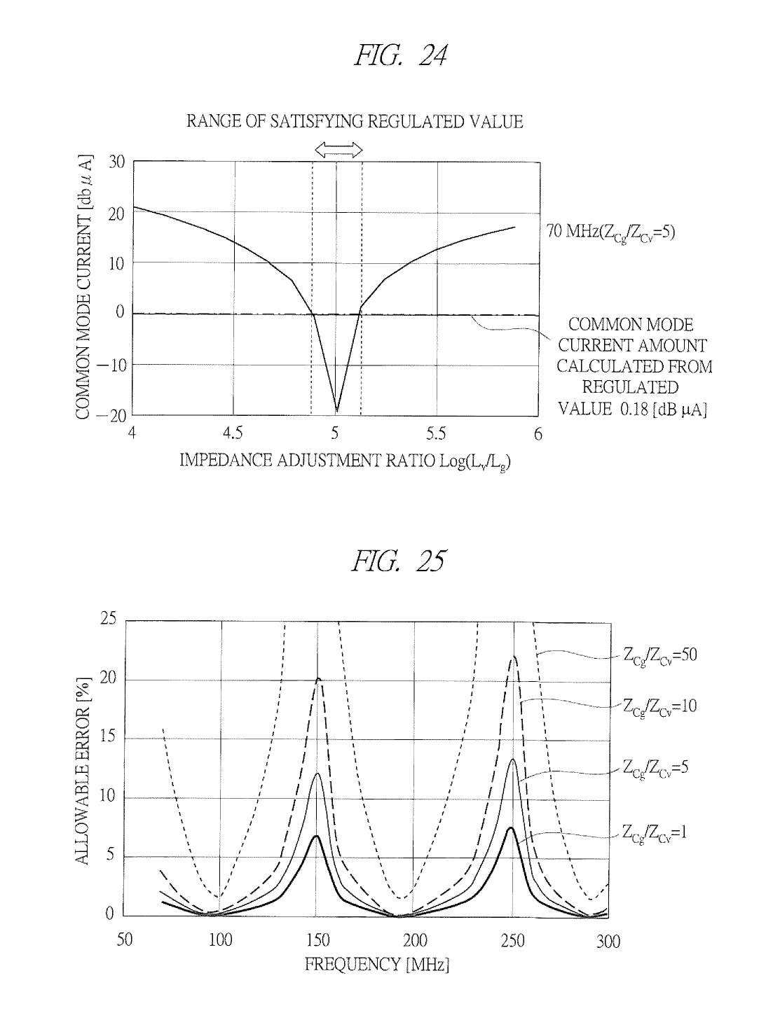

Here, in the equivalent circuit illustrated in FIG. 21, when the value of the common mode current in 70 MHz is calculated under conditions that Z_{Cv}=1 pF, Z_{Cg}=5 pF, Z_{Lg}=10 nH, Z_{Lv}=1 to 100 nH variable, and V_{d}=100 mV, a distribution as illustrated in FIG. 24 is obtained. FIG. 24 is a diagram illustrating a generation state of the common mode current 401 when the semiconductor device according to the first embodiment is mounted on the circuit board.

When the above-described regulated value is inputted into this distribution, the common mode current 401 can be suppressed to have the regulated value or smaller if the common mode current is within ±2% respectively from a value of Lᵥ/L_{g}=5 which is a balance point. Similarly, a value of the common mode current 401 satisfying the regulated value is calculated in a range from 80 MHz to 300 MHz, and an allowable error of the ratio β of the impedance multiplications is calculated.

FIG. 25 is a diagram illustrating the allowable error of the ratio of the impedance multiplications when the semiconductor device according to the first embodiment is mounted on the circuit board. At this time, an impedance ratio Z_{Cg}/Z_{Cv} is set to be variable from 1 to 50. As illustrated in FIG. 25, in vicinities of frequencies of 100 MHz, 200 MHz, and 300 MHz at which the power cable 202 resonates, the error is required to be 3% or smaller. Contrarily, it is found out that, in the frequencies other than the resonance frequencies, the regulated value can be satisfied even when the error is large.

In the foregoing, the invention made by the inventors has been concretely described based on the embodiments. However, it is needless to say that the present invention is not limited to the foregoing embodiments and various modifications and alterations can be made within the scope of the present invention.

For example, as described above, if the condition of balancing the bridge circuit in FIG. 4, 9, 11, or others can be satisfied, all of the impedance adjusting elements 31, 32, 33, and 34 are not required, and a configuration without any of them may be provided. Further, the impedance adjusting elements 31, 32, 33, and 34 are not required to be elements, and may be configured by a wiring pattern of a circuit so that their wiring impedances are used.

### INDUSTRIAL APPLICABILITY

The present invention can be used for a semiconductor device capable of reducing a noise current.

1. A semiconductor device comprising:
a package board;
a semiconductor chip mounted on the package board;
a first wiring of supplying a first power supply potential to the semiconductor chip; and
a second wiring of supplying a second power supply potential lower than the first power supply potential to the semiconductor chip, wherein
the semiconductor device includes a conductive plate having a third potential different from the first power supply potential and the second power supply potential, and
the semiconductor device further includes at least one of:
a first element arranged on a path of the first wiring for adjusting impedances of the first wiring and the second wiring; and
a second element arranged on a path of the second wiring for adjusting the impedances of the first wiring and the second wiring.

2. The semiconductor device according to claim 1, wherein,
in a first impedance of a parasitic capacitance between the first wiring and the conductive plate,
a second impedance of a parasitic capacitance between the second wiring and the conductive plate,
a third impedance obtained by synthesizing an impedance of a parasitic inductance of the first wiring with an impedance of the first element, and
a fourth impedance obtained by synthesizing an impedance of a parasitic inductance of the second wiring with an impedance of the second element,
the impedances of the first element and the second element are adjusted so that multiplication of the first impedance with the fourth impedance is equal to multiplication of the second impedance with the third impedance in a range of error of 3%.

3. A semiconductor device comprising:
a package board;
a semiconductor chip mounted on the package board;
a first wiring of supplying a first power supply potential to the semiconductor chip; and
a second wiring of supplying a second power supply potential lower than the first power supply potential to the semiconductor chip, wherein
the semiconductor device includes a conductive plate having a third potential different from the first power supply potential and the second power supply potential, and
the semiconductor device further includes at least one of:
a first element arranged on a path between the first wiring and the conductive plate for adjusting impedances of the first wiring and the second wiring; and
a second element arranged on a path between the second wiring and the conductive plate for adjusting the impedances of the first wiring and the second wiring.

4. The semiconductor device according to claim 3, wherein,
in a first impedance obtained by synthesizing an impedance of the first element with an impedance of a parasitic capacitance between the first wiring and the conductive plate,
a second impedance obtained by synthesizing an impedance of the second element with an impedance of a parasitic capacitance between the second wiring and the conductive plate,
a third impedance of a parasitic inductance of the first wiring, and
a fourth impedance of a parasitic inductance of the second wiring,
the impedances of the first element and the second element are adjusted so that multiplication of the first impedance with the fourth impedance is equal to multiplication of the second impedance with the third impedance in a range of error of 3%.

5. A semiconductor device comprising:
a package board;
a semiconductor chip mounted on the package board;
a first wiring of supplying a first power supply potential to the semiconductor chip; and
a second wiring of supplying a second power supply potential lower than the first power supply potential to the semiconductor chip, wherein
the semiconductor device includes a conductive plate having a third potential different from the first power supply potential and the second power supply potential, and
the semiconductor device further includes at least one of:
a first element arranged on a path of the first wiring for adjusting impedances of the first wiring and the second wiring;
a second element arranged on a path between the first wiring and the conductive plate for adjusting the impedances of the first wiring and the second wiring;
a third element arranged on a path of the second wiring for adjusting impedances of the first wiring and the second wiring; and
a fourth element arranged on a path between the second wiring and the conductive plate for adjusting the impedances of the first wiring and the second wiring.

6. The semiconductor device according to claim 5, wherein,
in a first impedance obtained by synthesizing an impedance of the second element with an impedance of a parasitic capacitance between the first wiring and the conductive plate,
a second impedance obtained by synthesizing an impedance of the fourth element with an impedance of a parasitic capacitance between the second wiring and the conductive plate,
a third impedance obtained by synthesizing an impedance of the first element with an impedance of a parasitic inductance of the first wiring, and
a fourth impedance obtained by synthesizing an impedance of the third element with an impedance of a parasitic inductance of the second wiring,
the impedances of the first element to the fourth element are adjusted so that multiplication of the first impedance with the fourth impedance is equal to multiplication of the second impedance with the third impedance in a range of error of 3%.

7. The semiconductor device according to claim 1, wherein
an element for adjusting the impedances of the first wiring and the second wiring is configured by a wiring pattern.
